(19) United States
(12) Patent Application Publication
(10) Pub. No.: US 2018/0294777 A1
(43) Pub. Date: Oct. 11, 2018

(54) COMPACT LOAD NETWORK FOR DOHERTY POWER AMPLIFIER USING LUMPED COMPONENTS

(71) Applicant: RESEARCH & BUSINESS FOUNDATION SUNGKYUNKWAN UNIVERSITY, Suwon-si (KR)

(72) Inventors: Youngoo YANG, Hwaseong-si (KR); Hwiseob LEE, Ansan-si (KR); Wonseob LIM, Ansan-si (KR)

(73) Assignee: RESEARCH & BUSINESS FOUNDATION SUNGKYUNKWAN UNIVERSITY, Suwon-si (KR)

(21) Appl. No.: 15/840,228

(22) Filed: Dec. 13, 2017

(30) Foreign Application Priority Data
Apr. 7, 2017 (KR) 10-2017-0045050

(51) Int. Cl. H03F 1/02; H03F 1/56; H03F 3/193; H03F 3/21

(52) U.S. Cl. CPC H03F 1/0288; H03F 1/565; H03F 3/193; H03F 2200/391; H03F 2200/451; H03F 2200/387; H03F 3/21

(57) ABSTRACT

A compact load network for a Doherty power amplifier includes a first inductor, a second inductor, a series capacitor, and a filter unit. The first inductor is configured such that one terminal thereof is connected to a drain voltage terminal and a remaining terminal thereof is connected in parallel to an output terminal of a first transistor. The second inductor is configured such that one terminal thereof is connected to a drain voltage terminal and a remaining terminal thereof is connected in parallel to an output terminal of a second transistor. The series capacitor is connected in series between the output terminal of the first transistor and the output terminal of the second transistor. The filter unit is connected between the output terminal of the second transistor and a signal output terminal.

### CROSS-REFERENCE TO RELATED APPLICATION

This application claims the benefit under 35 USC 119(a) of Korean Patent Application No. 10-2017-0045050 filed on Apr. 7, 2017 in the Korean Intellectual Property Office, the entire disclosure of which is incorporated herein by reference for all purposes.

### BACKGROUND

### 1. Field

The following description relates to a load network for a Doherty power amplifier, and more specifically to a compact load network for a Doherty power amplifier using lumped component.

### 2. Description of the Related Art

A Doherty power amplifier corresponds to a scheme capable of improving efficiency in a backoff region at maximum output power, and is one of the most widely used schemes in wireless communication transmission systems.

FIG. 1 is a block diagram of a conventional load network for a Doherty power amplifier.

Referring to FIG. 1, carrier and peaking amplifiers are matched to R₀ via respective matching networks, and then appropriate impedance can be exhibited in high output and in low output mode via respective offset lines. Furthermore, desired load impedance modulation can be achieved by applying a λ/4 impedance converter by using a transmission line.

However, in order to achieve appropriate load impedance modulation, it is unavoidable to apply a plurality of λ/4 impedance converters, matching networks, and offset lines to the load network. These elements are implemented on a substrate or module in the form of transmission lines having specific lengths based on frequency, and thus require a considerable size. Furthermore, as the number of stages or ways in a Doherty structure increases, the size and complexity of the load network must also increase further.

As described above, the plurality of transmission line-type elements is used, and thus a limitation is imposed on a reduction of the size of the overall load network.

In order to overcome the above problem, a method of implementing a load network for a Doherty power amplifier by using lumped components is proposed. When lumped components are used, an advantage arises in that a smaller and simpler implementation can be made than a method using transmission lines on a substrate, but loss is relatively high. Accordingly, the problem of a reduction in performance, such as output power or efficiency, may occur. In particular, the use of an inductor in a load network significantly influences loss, and thus the use of an inductor must be minimized. Furthermore, these phenomena generally become more serious as frequency increases, and thus there occurs further difficulty with implementation.

### SUMMARY

The present disclosure is intended to provide a compact load network for a Doherty power amplifier which can be implemented using lumped components in a simpler structure than the conventional load network, thereby achieving the overall improvement of performance.

In one general aspect, a compact load network for a Doherty power amplifier includes a first inductor, a second inductor, a series capacitor, and a filter unit. The first inductor is configured such that one terminal thereof is connected to a drain voltage terminal and a remaining terminal thereof is connected in parallel to an output terminal of a first transistor. The second inductor is configured such that one terminal thereof is connected to a drain voltage terminal and a remaining terminal thereof is connected in parallel to an output terminal of a second transistor. The series capacitor is connected in series between the output terminal of the first transistor and the output terminal of the second transistor. The filter unit is connected between the output terminal of the second transistor and a signal output terminal.

The first inductor may be a carrier inductor. The first transistor may be a carrier transistor. The second inductor may be a peaking inductor, and the second transistor may be a peaking transistor.

The filter unit may be a high-pass filter unit or a low-pass filter unit.

The high-pass filter unit may include a filter capacitor connected in series and a filter inductor connected in parallel.

The low-pass filter unit may include a filter inductor connected in series and a filter capacitor connected in parallel.

In another general aspect, a compact load network for a Doherty power amplifier includes a first inductor configured such that one terminal thereof is connected to a drain voltage terminal and a remaining terminal thereof is connected in parallel to an output terminal of a first transistor; second inductors each configured such that one terminal thereof is connected to a drain voltage terminal and a remaining terminal thereof is connected in parallel to an output terminal of a corresponding one of second transistors; a series capacitor connected in series between the output terminal of the first transistor and an output terminal of an adjacent one of the second transistors; and a filter unit connected between output terminals of the second transistors and a signal output terminal.

In another general aspect, a compact load network for a Doherty power amplifier includes a first inductor configured such that one terminal thereof is connected to a drain voltage terminal and a remaining terminal thereof is connected in parallel to an output terminal of a first transistor; a second inductor configured such that one terminal thereof is connected to a drain voltage terminal and a remaining terminal thereof is connected in parallel to an output terminal of any one of second transistors; a series capacitor connected in series between the output terminal of the first transistor and an output terminal of an adjacent one of the second transistors; and a filter unit connected between output terminals of the second transistors and a signal output terminal.

Other features and aspects will be apparent from the following detailed description, the drawings, and the claims.

### BRIEF DESCRIPTION OF THE DRAWINGS

FIG. 1 is a block diagram of a conventional typical load network for a Doherty power amplifier.

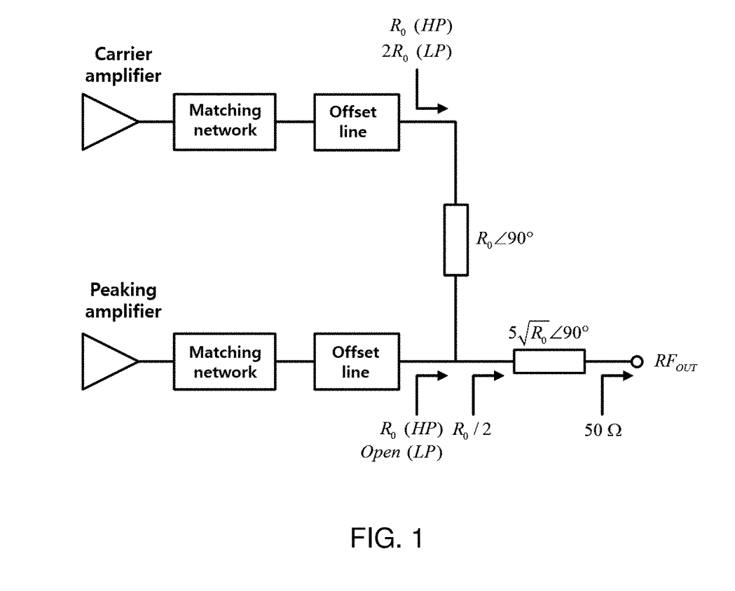

FIG. 2 is a circuit diagram of an example of a compact load network for a Doherty power amplifier using lumped components.

FIG. 3 is a circuit diagram of an example of a compact load network for a Doherty power amplifier.

FIG. 4 is a Smith chart of the compact load network for the Doherty power amplifier of FIG. 3.

FIG. 5 is a circuit diagram of an example of an N-way load network for a Doherty power amplifier.

FIG. 6 is a circuit diagram of another example of an N-way load network for a Doherty power amplifier.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

The features of the examples described herein may be combined in various ways as will be apparent after an understanding of the disclosure of this application. Further, although the examples described herein have a variety of configurations, other configurations are possible as will be apparent after an understanding of the disclosure of this application

The present disclosure is intended to provide a compact load network for a Doherty power amplifier which can be implemented using lumped components in a simpler structure than the conventional load network, thereby achieving the overall improvement of performance.

A compact load network for a Doherty amplifier according to the present disclosure will be described in conjunction with the accompanying drawings. The compact load network for a Doherty amplifier according to the present disclosure may include a high-pass filter unit or low-pass filter unit. However, for ease of description, the following description will be given with a focus on the high-pass filter unit.

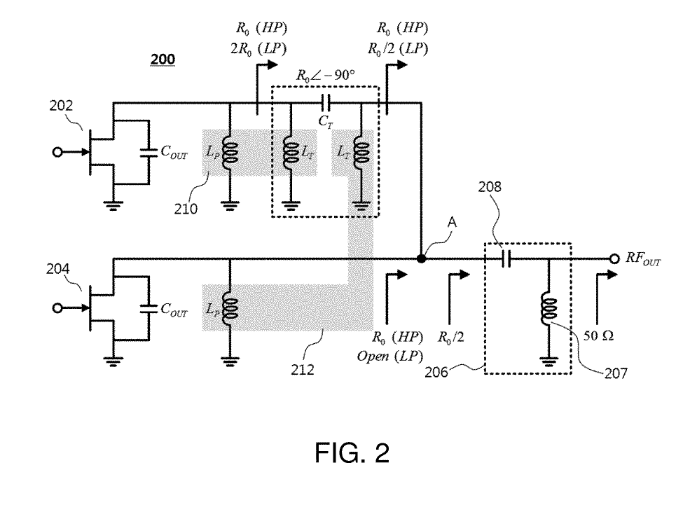

FIG. 2 is a circuit diagram of an example of a compact load network for a Doherty power amplifier using lumped components.

Referring to FIG. 2, an example of a compact load network 200 for a Doherty power amplifier using lumped components is shown. Since the output capacitance of each transistor can be compensated for using a shunt inductor L_{P}, load impedance appears to be a pure resistance component R₀. Due to a low gate voltage, a peaking amplifier 204 operating in a Class-C condition allows impedance to appear to be open in low output mode without an additional offset line. In order to achieve the appropriate load impedance modulation of a carrier amplifier, a high-pass filter-type quarter-wave (λ/4) impedance converter having characteristic impedance R₀ is implemented using lumped components L_{T} and C_{T}. Since the λ/4 impedance converter is implemented in the form of a high-pass filter, the shunt inductors can be merged with other adjacent inductors later, and can be also used to apply a drain bias. Furthermore, a compact high-pass filter-type matching network 206 is applied between a node at which the carrier amplifier 202 and the peaking amplifier 204 are connected and a final RF output of 50 Ω. The implementation of the compact high-pass filter-type matching network 206 is such that impedance matching can be achieved without a series inductor which reflects loss into the load network without change.

For reference, the compact load network 200 for the Doherty power amplifier uses a minimum number of lumped components. Load impedance is made to appear to be a pure resistance component R₀ by compensating for output capacitance C_{OUT} for each transistor cell constituting part of a Doherty power amplifier by using the shunt inductor L_{P}. Furthermore, appropriate load impedance modulation can be achieved via the high-pass filter-type λ/4 impedance converter, and a load network capable of realizing a significantly simple structure and minimizing loss compared to the conventional scheme can be implemented by merging the adjacent shunt inductors into single inductors 210 and 212. Moreover, loss can be minimized by the use of the high-pass filter-type L-C matching network 206 in which an inductor 207 connected in parallel is used between a node A at which the carrier amplifier 202 and the peaking amplifier 204 are connected and the final RF output of 50

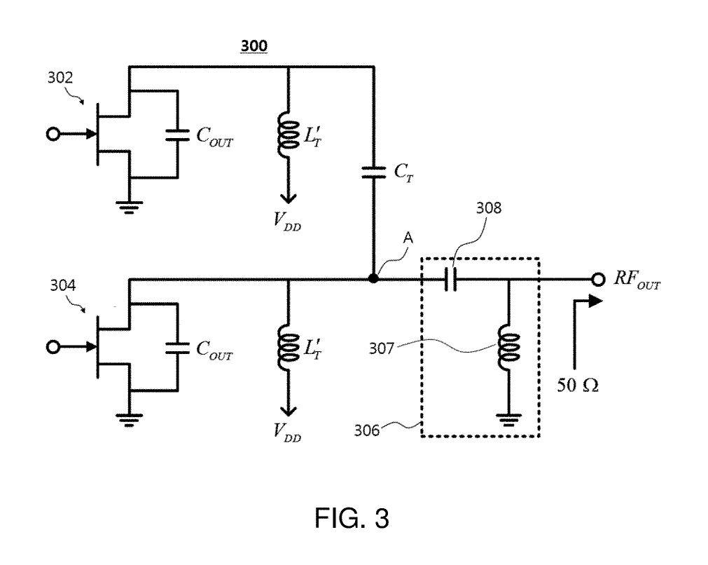

FIG. 3 is a circuit diagram of an example of a compact load network 300 for a Doherty power amplifier.

The compact load network 300 for a Doherty power amplifier according to the present embodiment includes a carrier transistor 302, a peaking transistor 304, a carrier inductor L′_{T}, a peaking inductor L′_{T}, a series capacitor C_{T}, and a high-pass filter unit 306.

One terminal of the carrier inductor L′_{T} is connected to a drain voltage terminal V_{DD}, and the other terminal thereof is connected in parallel to the output terminal of the carrier transistor Carrier.

One terminal of the peaking inductor L′_{T} is connected to a drain voltage terminal V_{DD}, and the other terminal thereof is connected in parallel to the output terminal of the peaking transistor 304.

The series capacitor C_{T} is connected between the output terminal of the carrier transistor 302 and the output terminal of the peaking transistor 304.

The high-pass filter unit 306 is connected between the output terminal of the peaking transistor 304 and a signal output terminal RF_{OUT}. The high-pass filter unit 306 is implemented using a filter capacitor 308 connected in series and a filter inductor 307 connected in parallel.

Referring to FIGS. 2 and 3 together, it can be seen that the embodiment shown in FIG. 3 has a form obtained by simplifying the load network of FIG. 2 through the merging of the adjacent shunt inductors into shunt inductors 210 and 212. In the present embodiment, the adjacent shunt inductors L_{P} and L_{T} 210 and L_{P} and L_{T} 212 are each merged into the single inductor L′_{T}, and a drain voltage V_{DD} can be applied to each of the carrier amplifier 302 and peaking amplifier 304. Furthermore, the series capacitor C_{T} of a high-pass filter-type matching network 306 can perform both an impedance matching function and a direct current (DC) blocking function. Accordingly, a load network for a Doherty power amplifier having any structure may be implemented to have a compact structure and low loss by using only three shunt inductors and only two series capacitors. Furthermore, an advantage arises in that a significantly compact load network can be implemented without a separate high-pass filter matching network because impedance is automatically coupled to 50 Ω in high output mode when R₀ is 100 Ω.

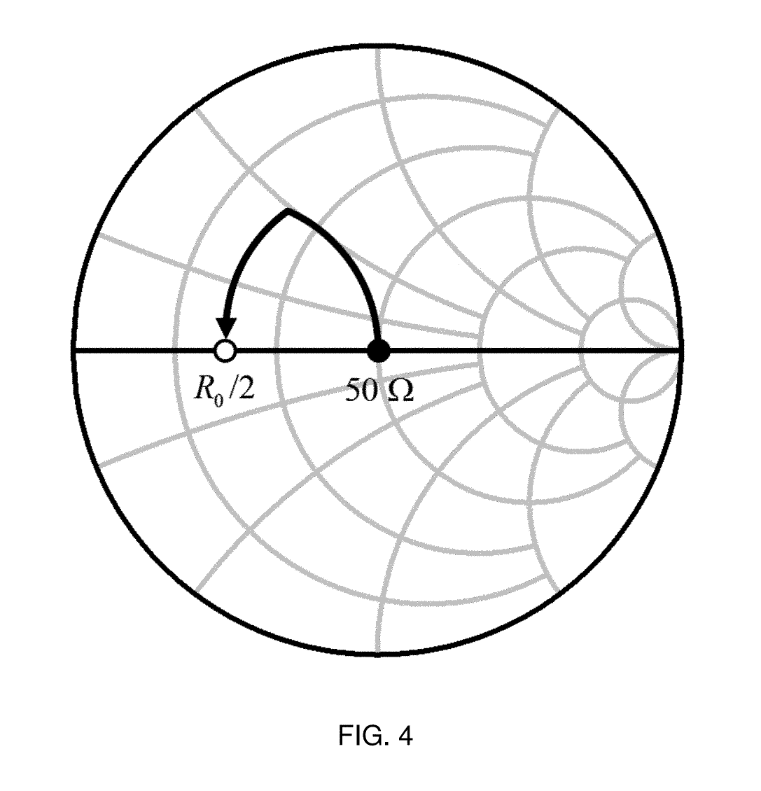

FIG. 4 is a Smith chart of the compact load network for the Doherty power amplifier of FIG. 3.

Referring to FIG. 4, generally, when R₀/2 is lower than 50 Ω, i.e., a final RF output impedance, the most simplest impedance matching trajectory can be seen.

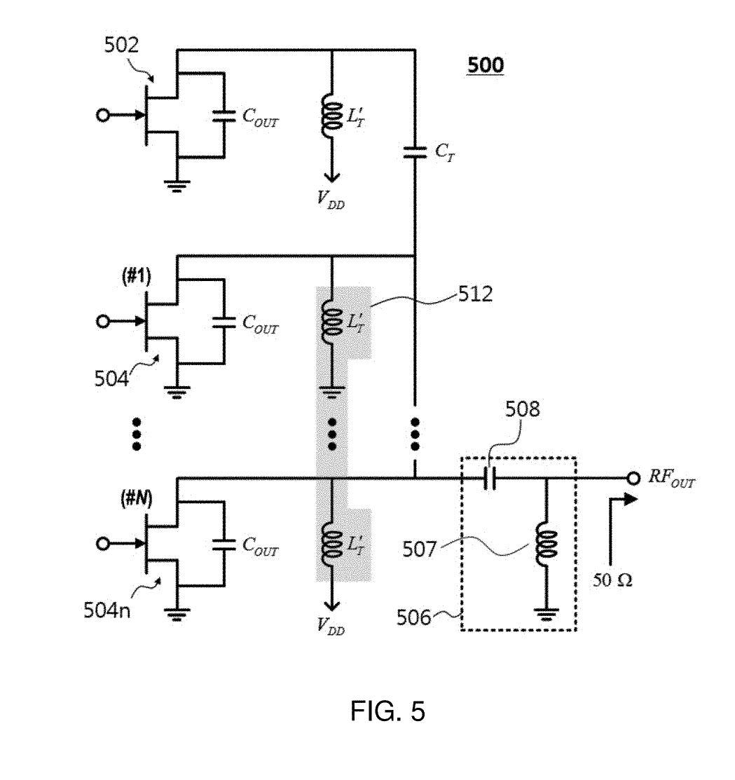

FIG. 5 is a circuit diagram of an example of an N-way load network 500 for a Doherty power amplifier.

Referring to FIG. 5, carrier amplifier 502 is connected in parallel with peaking amplifiers 504-504n, where n is an integer. FIG. 5 shows an N-way load network 500 that has a similar structure that includes peaking inductors L′_{T} connected in parallel to form single shunt inductor 512. Accordingly, increasing number of peaking amplifiers 504-504n that typically results in complexity of a circuit is now simplified through this disclosure.

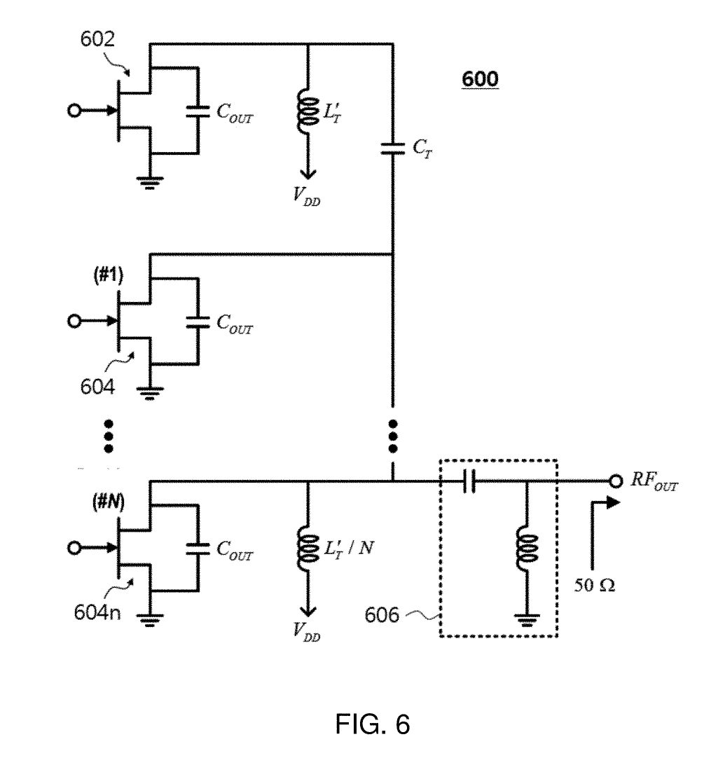

FIG. 6 is a circuit diagram of an N-way load network 600 for a Doherty power amplifier according to another example.

Referring to FIGS. 5 and 6 together, it can be seen that the example shown in FIG. 6 is formed by merging the peaking inductors L′_{T} connected to the same node, into a single inductor L′_{T}/N having a value of L′_{T}/N in the N-way load network for a Doherty power amplifier shown in FIG. 5, where N is an integer. Accordingly, the embodiment shown in FIG. 6 can be simplified into a structure in which the same drain voltage V_{DD} can be applied to the single merged inductor L′_{T}/N.

In order to implement a load network for a Doherty power amplifier in a small size, the load network for a Doherty power amplifier needs to be implemented using lumped components other than transmission lines. However, the lumped components have the disadvantage of having higher loss than the transmission lines, and are significantly limited in terms of the integration of inductors. The load network for a Doherty power amplifier according to the present disclosure uses a minimum number of lumped components, and thus has a considerably simple structure. The load network for a Doherty power amplifier according to the present disclosure can significantly reduce the number of lumped components which are used in the load network. In particular, the load network for a Doherty power amplifier according to the present disclosure does not use a series inductor which significantly influences loss, and can thus minimize a reduction in performance. This structure can be easily applied to N-way extension. Additionally, the proposed compact load network for a Doherty power amplifier can be applied to a micro base station system, such as a recently-developed small cell, or a small-sized power amplifier module for a mobile device. Furthermore, the proposed compact load network for a Doherty power amplifier can be applied to a radio frequency (RF) power transmitter for RF energy harvesting, and can thus contribute to the improvement of efficiency.

As described above, the compact load network for a Doherty power amplifier according to the present disclosure has the following advantages:

A compact load network having a simpler structure than the conventional load network can be implemented using lumped components, and thus a Doherty power amplifier capable of achieving the improvement of overall performance can be provided. Accordingly, the compact load network for a Doherty power amplifier according to the present disclosure can be significantly efficiently applied to a micro base station system, such as a recently-developed small cell, and a mobile device. Furthermore, the compact load network for a Doherty power amplifier according to the present disclosure can be applied to an RF power transmitter for RF energy harvesting, and can thus contribute to the improvement of efficiency.

The advantages of the present invention are not limited to the above-described advantages, and other advantages that have not been described will be readily apparent to those skilled in the art from the present specification.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A compact load network for a Doherty power amplifier, comprising:
a first inductor configured such that one terminal thereof is connected to a drain voltage terminal and a remaining terminal thereof is connected in parallel to an output terminal of a first transistor;
a second inductor configured such that one terminal thereof is connected to a drain voltage terminal and a remaining terminal thereof is connected in parallel to an output terminal of a second transistor;
a series capacitor connected in series between the output terminal of the first transistor and the output terminal of the second transistor; and
a filter unit connected between the output terminal of the second transistor and a signal output terminal.

2. The compact load network for a Doherty power amplifier of claim 1, wherein the first inductor is a carrier inductor, the first transistor is a carrier transistor, the second inductor is a peaking inductor, and the second transistor is a peaking transistor.

3. The compact load network for a Doherty power amplifier of claim 2, wherein the filter unit is a high-pass filter unit.

4. The compact load network for a Doherty power amplifier of claim 2, wherein the filter unit is a low-pass filter unit.

5. The compact load network of claim 3, wherein the high-pass filter unit comprises a filter capacitor connected in series and a filter inductor connected in parallel.

6. The compact load network of claim 4, wherein the low-pass filter unit comprises a filter inductor connected in series and a filter capacitor connected in parallel.

7. A compact load network for a Doherty power amplifier, comprising:
a first inductor configured such that one terminal thereof is connected to a drain voltage terminal and a remaining terminal thereof is connected in parallel to an output terminal of a first transistor;
second inductors each configured such that one terminal thereof is connected to a drain voltage terminal and a remaining terminal thereof is connected in parallel to an output terminal of a corresponding one of second transistors;
a series capacitor connected in series between the output terminal of the first transistor and an output terminal of an adjacent one of the second transistors; and
a filter unit connected between output terminals of the second transistors and a signal output terminal.

8. The compact load network for a Doherty power amplifier of claim 7, wherein the first inductor is a carrier inductor, the first transistor is a carrier transistor, the second inductor is a peaking inductor, and the second transistor is a peaking transistor.

9. The compact load network for a Doherty power amplifier of claim 8, wherein the filter unit is a high-pass filter unit.

10. The compact load network for a Doherty power amplifier of claim 8, wherein the filter unit is a low-pass filter unit.

11. The compact load network of claim 9, wherein the high-pass filter unit comprises a filter capacitor connected in series and a filter inductor connected in parallel.

12. The compact load network of claim 10, wherein the low-pass filter unit comprises a filter inductor connected in series and a filter capacitor connected in parallel.

13. A compact load network for a Doherty power amplifier, comprising:
a first inductor configured such that one terminal thereof is connected to a drain voltage terminal and a remaining terminal thereof is connected in parallel to an output terminal of a first transistor;
a second inductor configured such that one terminal thereof is connected to a drain voltage terminal and a remaining terminal thereof is connected in parallel to an output terminal of any one of second transistors;
a series capacitor connected in series between the output terminal of the first transistor and an output terminal of an adjacent one of the second transistors; and
a filter unit connected between output terminals of the second transistors and a signal output terminal.

14. The compact load network for a Doherty power amplifier of claim 13, wherein the first inductor is a carrier inductor, the first transistor is a carrier transistor, the second inductor is a peaking inductor, and the second transistor is a peaking transistor.

15. The compact load network for a Doherty power amplifier of claim 14, wherein the filter unit is a high-pass filter unit.

16. The compact load network for a Doherty power amplifier of claim 14, wherein the filter unit is a low-pass filter unit.

17. The compact load network of claim 15, wherein the high-pass filter unit comprises a filter capacitor connected in series and a filter inductor connected in parallel.

18. The compact load network of claim 16, wherein the low-pass filter unit comprises a filter inductor connected in series and a filter capacitor connected in parallel.
